(19) United States
(12) Patent Application Publication
(10) Pub. No.: US 2024/0023372 A1
(43) Pub. Date: Jan. 18, 2024

(54) ARRAY SUBSTRATE, MANUFACTURING METHOD THEREOF AND DISPLAY DEVICE

(71) Applicants: Wuhan China Star Optoelectronics Technology Co., Ltd., Wuhan, Hubei (CN); Wuhan China Star Optoelectronics Semiconductor Display Technology Co., Ltd., Wuhan, Hubei (CN)

(72) Inventor: Yu YAN, Wuhan (CN)

(21) Appl. No.: 17/608,146

(22) PCT Filed: Sep. 7, 2021
(86) PCT No.: PCT/CN2021/116844

§ 371 Date: Nov. 1, 2021

(30) Foreign Application Priority Data
Aug. 11, 2021 (CN) 202110917162.1

(51) Int. Cl. H10K 59/121; H10K 59/125; H10K 59/131; H10K 85/30

(52) U.S. Cl. CPC H10K 59/1213; H10K 59/125; H10K 59/131; H10K 85/331; H10K 2102/302

(57) ABSTRACT

An array substrate, a manufacturing method thereof and a display device are provided. The array substrate comprises a substrate, an active layer, a source and drain layer, a gate insulating layer and a gate. The active layer comprises an active section and a connecting section. The source and drain layer is disposed on the connecting section and contacts with the connecting section to be connected thereto; an area of a contact surface of the source and drain layer in contact with the connecting section is greater than an area of an orthographic projection of the contact surface of the source and drain layer in contact with the connecting section on the substrate.

### FIELD OF INVENTION

The present application relates to a display field, and more particularly to an array substrate, a manufacturing method thereof and a display device.

### BACKGROUND OF INVENTION

Low temperature polycrystalline oxide (LPTO) possesses similar properties to low temperature poly-silicon (LTPS) and higher electron mobility. Meanwhile, it can also be used with Indium Gallium Zinc Oxide (IGZO), to achieve the result of higher charge mobility at low production costs, and provide strong stability and scalability for the display panel. The display screen utilizing LTPO technology can greatly reduce the refreshing rate without additional devices, so that the device can save a lot of power by reducing the refreshing rate.

At present, when a semiconductor is in contact with a metal, a barrier layer is often formed. When the doping concentration of the semiconductor reaches a certain level, electrons can pass through the barrier due to the tunnel effect, and theoretically, a low-resistance ohmic contact layer is formed. However, doping has an adverse effect. When the doping is too much, the acceptor density will increase to form a high-surface-state semiconductor, causing the Fermi level pinning effect. The Fermi level in the original semiconductor is a parameter that is prone to change. Doping with donor impurities can move the Fermi level to the bottom of the conduction band, and the semiconductor becomes an n-type semiconductor; doping with acceptor impurities can move the Fermi level to the top of the valence band, and the semiconductor becomes a p-type semiconductor. However, in donors or acceptors with a large doped amount, the excessively doped impurities cannot be activated, nor can they provide carriers, so the position of the Fermi level cannot be changed. In such scenario, Fermi level pinning will occur. This effect will greatly reduce the electron mobility between the metal and the semiconductor, thereby weakening the display effect of the display panel.

The embodiments of the present application provide an array substrate, a manufacturing method thereof and a display device, so as to solve the technical problem that when the LTPO array substrate is excessively doped, the acceptor density becomes larger to form a high-surface-state semiconductor and form a Fermi level pinning effect.

### SUMMARY OF INVENTION

To solve the aforesaid problem, the technical solution of the present application is described as follows:

The embodiment of the present application further provides an array substrate, comprising:

a substrate;

an active layer arranged on the substrate, the active layer comprising an active section and a connecting section arranged on at least one side of the active section;

a source and drain layer, arranged on the connecting section and is in contact with the connecting section;

wherein an area of a contact surface of the source and drain layer in contact with the connecting section is greater than an area of an orthographic projection of the contact surface of the source and drain layer in contact with the connecting section on the substrate.

In the array substrate of the present application, a contact surface of the connecting section in contact with the source and drain layer comprises at least one first convex portion, and the source and drain layer comprises a first concave portion matching with the first convex portion.

In the array substrate of the present application, a supporting layer is provided between the active layer and the substrate, and the supporting layer comprises a supporting convex matching the first convex portion at a position corresponding to the first convex portion.

In the array substrate of the present application, a material of the supporting layer is silicon oxide or silicon nitride.

In the array substrate of the present application, the contact surface of the active layer in contact with the source and drain layer comprises at least one second concave portion, and the source and drain layer comprises a second convex portion matching with the second concave portion.

In the array substrate of the present application, an insulating layer is provided on the source and drain layer, and the insulating layer covers the active layer and the source and drain layer, and a gate groove is formed in the insulating layer, and a gate layer is formed in the gate groove, and a surface of the insulating layer away from the source and drain layer and a surface of the gate layer away from the source and drain layer are coplanar.

In the array substrate of the present application, the connecting section comprises a first connecting section and a second connecting section respectively connected to the active section, and the source and drain layer comprises a source arranged on the first connecting section and a drain arranged on the second connecting section, and a contact area of the source with the first connecting section is greater than an area of an orthographic projection of a contact surface of the source in contact with the first connecting section on the substrate, or a contact area of the drain with the second connecting section is greater than an area of an orthographic projection of a contact surface of the drain in contact with the second connecting section on the substrate.

In the array substrate of the present application, the source and drain layer comprises an oxide metal layer and a metal layer, and the metal layer is connected to the connecting section through the oxide metal layer, and an area of a contact surface of the oxide metal layer in contact with the connecting section is less than an area of a contact surface of the oxide metal layer in contact with the source and drain layer.

In the array substrate of the present application, a thickness of the metal oxide layer is less than 5 nm, and a material of the metal oxide layer is titanium oxide, cobalt oxide or nickel oxide.

The present application further provides a manufacturing method of an array substrate, comprising steps of:
forming a substrate;
forming an active layer on the substrate, and the active layer comprises an active section and a connecting section arranged on at least one side of the active section;
forming a source and drain layer on the connecting section and the source and drain layer is in contact with the connecting section;
wherein an area of a contact surface of the source and drain layer in contact with the connecting section is greater than an area of an orthographic projection of the contact surface of the source and drain layer in contact with the connecting section on the substrate.

The present application further provides a display panel, comprising an array substrate, and the array substrate comprises:
a substrate;
an active layer arranged on the substrate, the active layer comprising an active section and a connecting section arranged on at least one side of the active section;
a source and drain layer, arranged on the connecting section and is in contact with the connecting section;
wherein an area of a contact surface of the source and drain layer in contact with the connecting section is greater than an area of an orthographic projection of the contact surface of the source and drain layer in contact with the connecting section on the substrate.

In the display device of the present application, a contact surface of the connecting section in contact with the source and drain layer comprises at least one first convex portion, and the source and drain layer comprises a first concave portion matching with the first convex portion.

In the display device of the present application, a supporting layer is provided between the active layer and the substrate, and the supporting layer comprises a supporting convex matching the first convex portion at a position corresponding to the first convex portion.

In the display device of the present application, a material of the supporting layer is silicon oxide or silicon nitride.

In the display device of the present application, the contact surface of the active layer in contact with the source and drain layer comprises at least one second concave portion, and the source and drain layer comprises a second convex portion matching with the second concave portion.

In the display device of the present application, an insulating layer is provided on the source and drain layer, and the insulating layer covers the active layer and the source and drain layer, and a gate groove is formed in the insulating layer, and a gate layer is formed in the gate groove, and a surface of the insulating layer away from the source and drain layer and a surface of the gate layer away from the source and drain layer are coplanar.

In the display device of the present application, the connecting section comprises a first connecting section and a second connecting section respectively connected to the active section, and the source and drain layer comprises a source arranged on the first connecting section and a drain arranged on the second connecting section, and a contact area of the source with the first connecting section is greater than an area of an orthographic projection of a contact surface of the source in contact with the first connecting section on the substrate, or a contact area of the drain with the second connecting section is greater than an area of an orthographic projection of a contact surface of the drain in contact with the second connecting section on the substrate.

In the display device of the present application, the source and drain layer comprises an oxide metal layer and a metal layer, and the metal layer is connected to the connecting section through the oxide metal layer, and an area of a contact surface of the oxide metal layer in contact with the connecting section is less than an area of a contact surface of the oxide metal layer in contact with the source and drain layer.

In the display device of the present application, a thickness of the metal oxide layer is less than 5 nm, and a material of the metal oxide layer is titanium oxide, cobalt oxide or nickel oxide.

In the display device of the present application, the material of the metal oxide layer is nickel oxide.

In this application, the active layer and the source and drain layer are sequentially arranged in a direction perpendicular to the array substrate. The source and drain layer is connected to the connecting section of the active layer, and an area of a contact surface of the source and drain layer in contact with the connecting section is greater than an area of an orthographic projection of the contact surface of the source and drain layer in contact with the connecting section on the substrate, which effectively increases the contact area between the metal and the semiconductor, and can effectively alleviate the problem of Fermi level pinning caused by the formation of high-surface-states on the surface of the semiconductor due to the excessive doping of the semiconductor and the increase of the acceptor density, thus to improve the Fermi level pinning effect of the LTPO array substrate and the electron mobility between the metal and the semiconductor, thereby improving the display effect of the display panel.

### BRIEF DESCRIPTION OF THE DRAWINGS

FIG. 1 is a schematic structural diagram of an array substrate provided by an embodiment of the present application;

FIG. 2 is a schematic structural diagram of an array substrate provided by another embodiment of the present application;

FIG. 3 is a schematic structural diagram of a connecting section of an array substrate comprising a plurality of first convex portions according to an embodiment of the present application;

FIG. 4 is a schematic structural diagram of a connecting section in an array substrate comprising a first convex portion and a second concave portion according to an embodiment of the present application;

FIG. 5 is a schematic diagram of the structure of an array substrate provided by one another embodiment of the present application;

FIG. 6 is a schematic structural diagram of an array substrate with a source and drain layer comprising an oxide metal layer according to another embodiment of the present application;

FIG. 7 is a schematic diagram of a manufacturing process of an array substrate provided by an embodiment of the present application;

FIG. 8 is a schematic diagram of a manufacturing process of an array substrate provided by another embodiment of the present application;

FIG. 9 is a manufacturing flow chart of an array substrate provided by an embodiment of the present application.

### DETAILED DESCRIPTION OF PREFERRED EMBODIMENTS

The present invention provides an array substrate, a manufacturing method thereof and a display device. For the purpose, technical solutions and advantages of the present invention will become clear, unambiguous, embodiments of the present invention is described in further detail below with reference to the accompanying drawings simultaneously. It should be understood that the specific embodiments described herein are merely for explaining the present application and are not intended to limit the present application.

The embodiment of the present application provides an array substrate, a manufacturing method thereof and a display device. The detail descriptions are respectively introduced below. It should be noted that the order of description in the following embodiments is not meant to limit the preferred order of the embodiments.

At present, when a semiconductor is in contact with a metal, a barrier layer is often formed. When the doping concentration of the semiconductor reaches a certain level, electrons can pass through the barrier due to the tunnel effect, and theoretically, a low-resistance ohmic contact layer is formed.

However, doping has an adverse effect. When the doping is too much, the acceptor density will increase to form a high-surface-state semiconductor, causing the Fermi level pinning effect. The Fermi level in the original semiconductor is a parameter that is prone to change. Doping with donor impurities can move the Fermi level to the bottom of the conduction band, and the semiconductor becomes an n-type semiconductor; doping with acceptor impurities can move the Fermi level to the top of the valence band, and the semiconductor becomes a p-type semiconductor. However, in donors or acceptors with a large doped amount, the excessively doped impurities cannot be activated, nor can they provide carriers, so the position of the Fermi level cannot be changed. In such scenario, Fermi level pinning will occur. This effect will greatly reduce the electron mobility between the metal and the semiconductor, thereby weakening the display effect of the display panel.

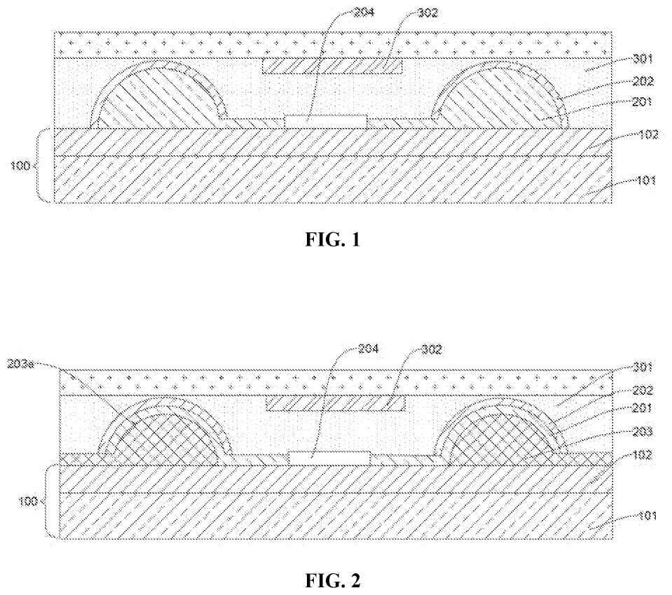

In order to solve the above technical problems, the present invention provides an array substrate, as shown in FIG. 1, comprising:

a substrate 100;

an active layer arranged on the substrate 100, the active layer comprising an active section and a connecting section 201 arranged on at least one side of the active section;

a source and drain layer 202, arranged on the connecting section 201 and is in contact with the connecting section 201;

wherein an area of a contact surface of the source and drain layer 202 in contact with the connecting section 201 is greater than an area of an orthographic projection of the contact surface of the source and drain layer 202 in contact with the connecting section 201 on the substrate 100.

Specifically, the substrate 100 comprises a base substrate 101 and a buffer layer 102 disposed on the base substrate 101. The active layer comprises an active section and a connecting section 201 arranged on at least one side of the active section. There may be two connecting sections 201, and the two connecting sections 201 may be respectively arranged on two sides of the active section or may be arranged on the same side of the active section. The material of the active section may be a semiconductor material, specifically a low-temperature polysilicon material, which may be doped with donor impurities to form an n-type semiconductor or may be doped with acceptor impurities to form a p-type semiconductor.

Specifically, a channel is also formed on the active section, and a metal oxide is filled in the channel, and the metal oxide may be IGZO.

Specifically, the active layer can be formed by chemical vapor deposition. After the film-formed semiconductor layer is obtained, ion implantation is performed to obtain the doped semiconductor connecting section 201, and then physical vapor deposition is performed to form an oxide layer, and then the field oxide 204 is formed by etching the oxide layer.

Specifically, the source and drain layer 202 formed on the active layer may be made of a metal material. The source and drain layer 202 may comprise a source and a drain, the source is connected to a connecting section 201 on an active layer, and the drain is connected to a connecting section 201 on another active layer. The source and the drain may be made of the same metal or different metals.

Specifically, as shown in FIG. 5, a dielectric layer 303 may be formed on the active layer, and the source and drain layer 202 is formed on the dielectric layer 303. Via holes are opened in the dielectric layer 303 at positions corresponding to the connecting sections 201, and the source and drain layer 202 is connected to the connecting sections 201 through the via holes.

Specifically, an area of a contact surface of the source and drain layer 202 in contact with the connecting section 201 is greater than an area of an orthographic projection of the contact surface of the source and drain layer 202 in contact with the connecting section 201 on the substrate 100. It can be understood that the contact surface between the source, the drain and the connecting section 201 is an undulating curved surface with a radian, and the cross section of the contact surface can be sawtooth, wavy or stepped, as long as the area of the contact surface between the source and drain layer 202 and the connecting section 201 can be increased, it is within the protection scope of the present application.

Specifically, the array substrate further comprises a gate layer, and the gate layer may be arranged below the active layer or above the active layer. The gate layer and the active layer are spaced apart by a gate insulating layer 301.

It is understandable that in a direction perpendicular to the array substrate, an area of a contact surface of the source and drain layer 202 in contact with the connecting section 201 is greater than an area of an orthographic projection of the contact surface of the source and drain layer 202 in contact with the connecting section 201 on the substrate 100, it effectively increases the contact area between the metal and the semiconductor, and can effectively alleviate the problem of Fermi level pinning caused by the formation of high-surface-states on the surface of the semiconductor due to the excessive doping of the semiconductor and the increase of the acceptor density, thus to improve the Fermi level pinning effect of the LTPO array substrate and the electron mobility between the metal and the semiconductor, and then to improve the display effect of the display panel.

In one embodiment, as shown in FIG. 1, a contact surface of the connecting section 201 in contact with the source and drain layer 202 comprises at least one first convex portion 201a, and the source and drain layer 202 comprises a first concave portion matching with the first convex portion 201a.

Specifically, the number of the first convex portions 201a is not limited, there may be one or more. The heights of the first convex portions 201a are also not limited, and may be the same or different. The shapes of the first convex portions 201a are not limited, and the cross-section can be a semi-ellipse with a certain radian or a square, as long as the solution can increase the contact area between the source and drain layer 202 and the connecting section 201, it is within the protection scope of this application.

Specifically, the first convex portion 201a may be disposed on the surface of the connecting section 201 connected to the source and drain layer 202, and on the corresponding source and drain layer 202 is a first concave portion matching with the first convex portion 201a; The first convex portion 201a may also be disposed on the surface of the source and drain layer 202 connected to the connecting section 201, and on the corresponding connecting section 201 is a first concave portion matching with the first convex portion 201a.

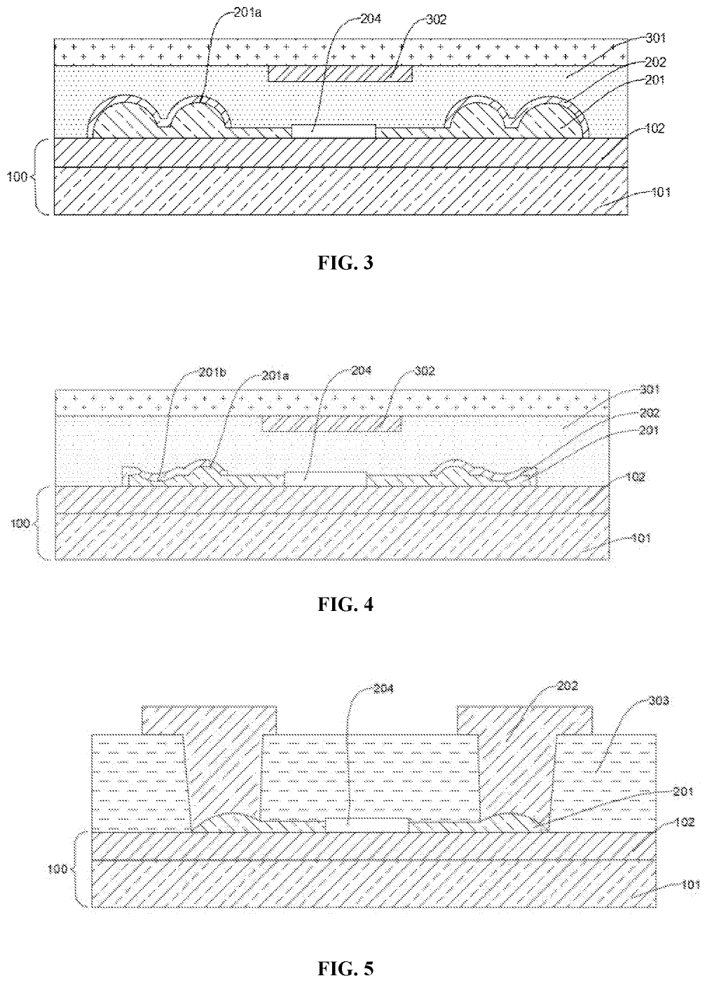

It can be understood that a contact surface of the connecting section 201 in contact with the source and drain layer 202 comprises at least one first convex portion 201a, and the source and drain layer 202 comprises a first concave portion matching with the first convex portion 201a. As shown in FIG. 3, FIG. 3 is an embodiment in which the contact surface of the connecting section 201 in contact with the source and drain layer 202 comprises two first convex portion 201a, which makes the manufacturing process simpler and reduces the production difficulty when the array substrate is manufactured.

In one embodiment, as shown in FIG. 2, a supporting layer 203 is provided between the active layer and the substrate 100, and the supporting layer 203 comprises a supporting convex 203a matching the first convex portion 201a at a position corresponding to the first convex portion 201a.

Specifically, the supporting layer 203 is disposed between the active layer and the substrate 100. Specifically, when the first convex portion 201a is provided on the connecting section 201, at this time, there is no concave portion on the connecting section 201, and these are all the first convex portions 201a. The supporting convex 203a is formed at the position of the supporting layer 203 corresponding to the first concave portion. The shape of the supporting convex 203a is similar to the shape of the first convex portion. Then, the thickness of the active layer on the supporting convex 203a is consistent. The material of the supporting layer 203 is an insulating material, which may be silicon oxide or silicon nitride.

It is understandable that by providing the supporting layer 203, the material of the supporting layer 203 is easier to perform etching and shaping operations than the material of the active layer, and the production cost is low. After the supporting layer 203 with the supporting convex 203a is formed, the connecting section 201 of the active layer is formed at the corresponding position on the supporting layer 203. It can be understood that the connecting section 201 covers the supporting convex 203a of the supporting layer 203. By adopting this scheme, it is easier to form an active layer with a curved surface in industrial production, and it is more practical in production with low production cost, and compared with the ordinary production process of the array substrate, there are fewer steps, and the ion conductivity is higher.

In one embodiment, as shown in FIG. 4, the contact surface of the active layer in contact with the source and drain layer 202 comprises at least one second concave portion 201b, and the source and drain layer 202 comprises a second convex portion matching with the second concave portion 201b.

It can be understood that the contact surface of the active layer in contact with the source and drain layer 202 further comprises the second concave portion 201b. It can be considered that there are both a first convex portion 201a and a second concave portion 201b on the contact surface of the connecting section 201 in contact with the source and drain layer 202. Compared with providing only the first convex portion 201a, the contact area between the active layer and the source and drain layer 202 is further increased, thus to improve the Fermi level pinning effect of the LTPO array substrate and the electron mobility between the metal and the semiconductor, and then to improve the display effect of the display panel.

In one embodiment, as shown in FIG. 1, an insulating layer is provided on the source and drain layer 202, and the insulating layer covers the active layer and the source and drain layer 202, and a gate groove is formed in the insulating layer, and a gate layer is formed in the gate groove, and a surface of the insulating layer away from the source and drain layer 202 and a surface of the gate layer away from the source and drain layer 202 are coplanar.

It can be understood that, in the present technical solution, the structure of the array substrate is a top gate structure, and the gate 302 is located above the active layer, and the insulating layer is the gate insulating layer 301. The gate insulating layer 301 is provided so that its upper surface is in a planar state, so that the gate insulating layer 301 does not only function for planarization but also functions as a gate insulating layer 301, which further reduces the thickness of the array substrate.

In one embodiment, the connecting section 201 comprises a first connecting section and a second connecting section respectively connected to the active section, and the source and drain layer 202 comprises a source arranged on the first connecting section and a drain arranged on the second connecting section, and a contact area of the source with the first connecting section is greater than an area of an orthographic projection of a contact surface of the source in contact with the first connecting section on the substrate 100, or a contact area of the drain with the second connecting section is greater than an area of an orthographic projection of a contact surface of the drain in contact with the second connecting section on the substrate 100.

Specifically, a contact area of the source with the first connecting section is greater than an area of an orthographic projection of a contact surface of the source in contact with the first connecting section on the substrate 100, and at least one first sub-convex portion may be provided on the first connecting section, and a first sub-concave portion corresponding to the first sub-convex portion is provided on the corresponding source; or a contact area of the drain with the second connecting section is greater than an area of an orthographic projection of a contact surface of the drain in contact with the second connecting section on the substrate 100, and at least one second sub-convex portion may be provided on the second connecting section, and a second sub-concave portion corresponding to the second sub-convex portion is provided on the corresponding drain.

It can be understood that only the first sub-convex portion may be provided on the first connecting section, or only the second sub-convex portion may be separately provided on the second connecting section. Alternately, the first sub-convex portion is provided on the first connecting section and the second sub-convex portion is provided on the second connecting section at the same time. The above technical solution effectively increases the contact area between the metal and the semiconductor, and can effectively alleviate the problem of Fermi level pinning caused by the formation of high-surface-states on the surface of the semiconductor due to the excessive doping of the semiconductor and the increase of the acceptor density, thus to improve the Fermi level pinning effect of the LTPO array substrate and the electron mobility between the metal and the semiconductor, and then to improve the display effect of the display panel.

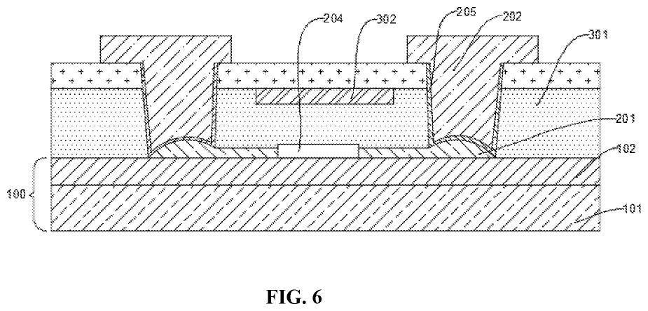

In one embodiment, as shown in FIG. 6, the source and drain layer 202 comprises an oxide metal layer 205 and a metal layer, and the metal layer is connected to the connecting section 201 through the oxide metal layer 205, and an area of a contact surface of the oxide metal layer 205 in contact with the connecting section 201 is less than an area of a contact surface of the oxide metal layer 205 in contact with the source and drain layer 202.

Specifically, a material of the metal oxide layer 205 may be titanium oxide. The material of the metal oxide layer 205 may also be cobalt oxide and nickel oxide.

It is understandable that the metal oxide layer 205 possess a lower valence band, so the metal oxide layer 205 can effectively reduce the density of states in the forbidden band of the connecting section 201 of the active layer, thereby effectively reducing the occurrence of metal-induced gap states. This can effectively suppress the Fermi level pinning phenomenon at the interface between the source and drain layer 202 and the connecting section 201 of the active layer, thus to reduce the contact resistance between the source and drain layer 202 and the connecting section 201 of the active layer, which is beneficial to improve the performance of the formed semiconductor structure.

In one embodiment, a thickness of the metal oxide layer 205 is less than 5 nm, and a material of the metal oxide layer 205 is titanium oxide, cobalt oxide or nickel oxide.

Specifically, since the thickness of the metal oxide layer 205 is smaller, electrons can tunnel through the metal oxide layer 205. Thus, the metal oxide layer 205 can improve the interface performance between the source and drain layer 202 and the connecting section 201 of the active layer without affecting the conductivity between the source and drain layer 202 and the connecting section 201 of the active layer. This effectively suppress the phenomenon of Fermi level pinning at the interface between the plug and the source and drain doped regions, which is beneficial to reduce the contact resistance between the plug and the source and drain doped regions and is beneficial to improve the performance of the formed semiconductor structure.

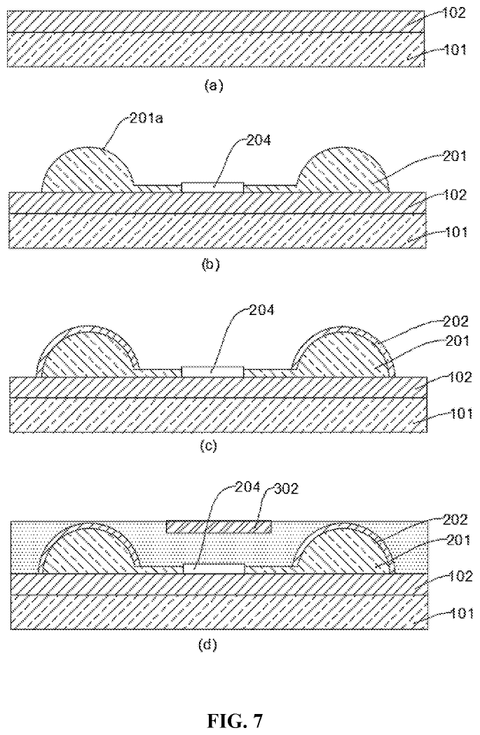

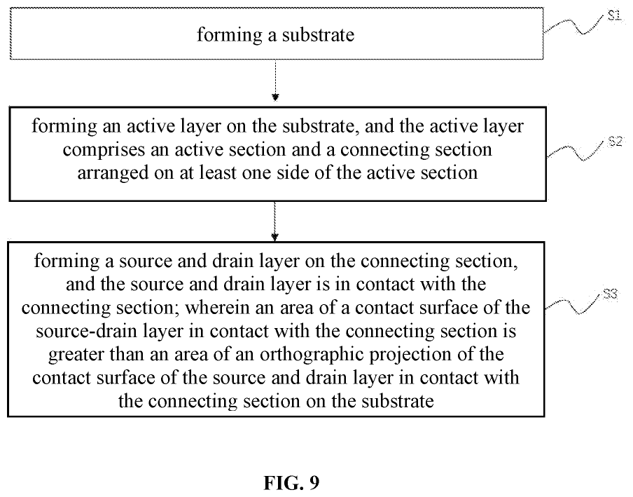

The present application further provides a manufacturing method of an array substrate, as shown in FIG. 7 and FIG. 9, comprising steps of:

S1, forming a substrate 100;

S2, forming an active layer on the substrate 100, and the active layer comprises an active section and a connecting section 201 arranged on at least one side of the active section;

S3, forming a source and drain layer 202 on the connecting section 201, and the source and drain layer 202 is in contact with the connecting section 201; wherein an area of a contact surface of the source and drain layer 202 in contact with the connecting section 201 is greater than an area of an orthographic projection of the contact surface of the source and drain layer 202 in contact with the connecting section 201 on the substrate 100.

Specifically, a gate insulating layer 301 is further formed on the source and drain layer 202, and a gate 302 is formed on the gate insulating layer 301 to form a top gate structure.

Specifically, the manufacturing process of FIG. 7 is described as follows:

As shown in FIG. 7(a), forming a substrate 100;

As shown in FIG. 7(b), forming an active layer on the substrate 100, and the active layer comprises an active section and a connecting section 201 arranged on at least one side of the active section;

As shown in FIG. 7(c), forming a source and drain layer 202 on the connecting section 201, and the source and drain layer 202 is in contact with the connecting section 201; wherein an area of a contact surface of the source and drain layer 202 in contact with the connecting section 201 is greater than an area of an orthographic projection of the contact surface of the source and drain layer 202 in contact with the connecting section 201 on the substrate 100.

Specifically, as shown in FIG. 7(d), further forming a gate insulating layer 301 on the source and drain layer 202, and forming a gate 302 on the gate insulating layer 301 to form a top gate structure.

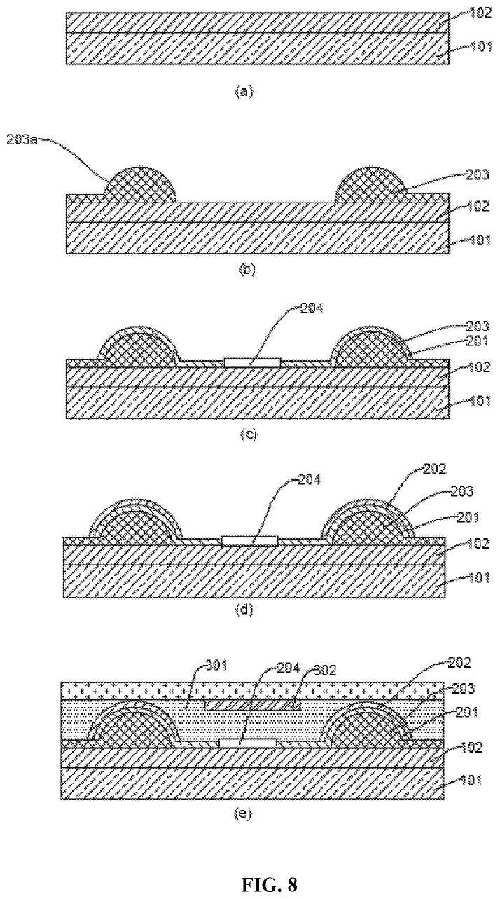

In another embodiment, the manufacturing method of the array substrate, as shown in FIG. 8, comprises the following steps:

As shown in FIG. 8(a), forming a substrate 100, and the substrate 100 comprises a base substrate 101 and a buffer layer 102 disposed on the base substrate 101. The base substrate 101 may be coated by polyimide resin, and the buffer layer 102 may be formed by chemical vapor deposition.

As shown in FIG. 8(b), forming a supporting layer 203, and a material of the supporting layer 203 may be silicon nitride, and a supporting convex 203a is provided on the supporting layer 203 at a position corresponding to the connecting section 201 of the active layer.

As shown in FIG. 8(c), forming an active layer on the supporting layer 203 and the substrate 100. The active layer comprises an active section and a connecting section 201 arranged on at least one side of the active section; wherein there may be two connecting sections 201, and the two connecting sections 201 may be respectively arranged on two sides of the active section. Before the formation of the active layer, ion implantation is performed on the semiconductor material and the doping operation is performed, and then the doped semiconductor is deposited on the supporting layer 203, and the doped semiconductor layer is etched to form an oxide channel, and the field oxide 204 is deposited in the oxide channel.

As shown in FIG. 8(d), forming a source and drain layer 202 on the connecting section 201, and the source and drain layer 202 is in contact with the connecting section 201; wherein an area of a contact surface of the source and drain layer 202 in contact with the connecting section 201 is greater than an area of an orthographic projection of the contact surface of the source and drain layer 202 in contact with the connecting section 201 on the substrate 100.

Specifically, as shown in FIG. 8(e), this manufacturing method further comprises a step of forming an insulating layer on the source and drain. The insulating layer covers the active layer and the source and drain layer 202. A gate layer is formed on the insulating layer, and a second insulating layer covering the gate layer and the insulating layer is formed on the gate layer.

It is understandable that in a direction perpendicular to the array substrate 100, an area of a contact surface of the source and drain layer 202 in contact with the connecting section 201 is greater than an area of an orthographic projection of the contact surface of the source and drain layer 202 in contact with the connecting section 201 on the substrate 100, it effectively increases the contact area between the metal and the semiconductor, and can effectively alleviate the problem of Fermi level pinning caused by the formation of high-surface-states on the surface of the semiconductor due to the excessive doping of the semiconductor and the increase of the acceptor density, thus to improve the Fermi level pinning effect of the LTPO array substrate and the electron mobility between the metal and the semiconductor, and then to improve the display effect of the display panel.

The present invention further provides a display device. The display device comprises the array substrates described in any of the aforesaid embodiments.

In conclusion, in a direction perpendicular to the array substrate, an area of a contact surface of the source and drain layer in contact with the connecting section is greater than an area of an orthographic projection of the contact surface of the source and drain layer in contact with the connecting section on the substrate, it effectively increases the contact area between the metal and the semiconductor, and can effectively alleviate the problem of Fermi level pinning caused by the formation of high-surface-states on the surface of the semiconductor due to the excessive doping of the semiconductor and the increase of the acceptor density, thus to improve the Fermi level pinning effect of the LTPO array substrate and the electron mobility between the metal and the semiconductor, and then to improve the display effect of the display panel.

The array substrate, manufacturing method thereof and the display device provided by the embodiments of the present application are described in detail as aforementioned, and the principles and implementations of the present application have been described with reference to specific illustrations. The description of the foregoing embodiments is merely for helping to understand the technical solutions of the present application and the core ideas thereof; meanwhile, those skilled in the art will be able to change the specific embodiments and the scope of the application according to the idea of the present application. In conclusion, the content of the specification should not be construed as limiting the present application.

What is claimed is:

1. An array substrate, comprising:
a substrate;
an active layer arranged on the substrate, the active layer comprising an active section and a connecting section arranged on at least one side of the active section;
a source and drain layer, arranged on the connecting section and is in contact with the connecting section;
wherein an area of a contact surface of the source and drain layer in contact with the connecting section is greater than an area of an orthographic projection of the contact surface of the source and drain layer in contact with the connecting section on the substrate.

2. The array substrate according to claim 1, wherein a contact surface of the connecting section in contact with the source and drain layer comprises at least one first convex portion, and the source and drain layer comprises a first concave portion matching with the first convex portion.

3. The array substrate according to claim 2, wherein a supporting layer is provided between the active layer and the substrate, and the supporting layer comprises a supporting convex matching the first convex portion at a position corresponding to the first convex portion.

4. The array substrate according to claim 3, wherein a material of the supporting layer is silicon oxide or silicon nitride.

5. The array substrate according to claim 2, wherein the contact surface of the active layer in contact with the source and drain layer comprises at least one second concave portion, and the source and drain layer comprises a second convex portion matching with the second concave portion.

6. The array substrate according to claim 2, wherein an insulating layer is provided on the source and drain layer, and the insulating layer covers the active layer and the source and drain layer, and a gate groove is formed in the insulating layer, and a gate layer is formed in the gate groove, and a surface of the insulating layer away from the source and drain layer and a surface of the gate layer away from the source and drain layer are coplanar.

7. The array substrate according to claim 1, wherein the connecting section comprises a first connecting section and a second connecting section respectively connected to the active section, and the source and drain layer comprises a source arranged on the first connecting section and a drain arranged on the second connecting section, and a contact area of the source with the first connecting section is greater than an area of an orthographic projection of a contact surface of the source in contact with the first connecting section on the substrate, or a contact area of the drain with the second connecting section is greater than an area of an orthographic projection of a contact surface of the drain in contact with the second connecting section on the substrate.

8. The array substrate according to claim 1, wherein the source and drain layer comprises an oxide metal layer and a metal layer, and the metal layer is connected to the connecting section through the oxide metal layer, and an area of a contact surface of the oxide metal layer in contact with the connecting section is less than an area of a contact surface of the oxide metal layer in contact with the source and drain layer.

9. The array substrate according to claim 8, wherein a thickness of the metal oxide layer is less than 5 nm, and a material of the metal oxide layer is titanium oxide, cobalt oxide or nickel oxide.

10. A manufacturing method of an array substrate, comprising steps of:
forming a substrate;
forming an active layer on the substrate, and the active layer comprises an active section and a connecting section arranged on at least one side of the active section;
forming a source and drain layer on the connecting section and the source and drain layer is in contact with the connecting section;
wherein an area of a contact surface of the source and drain layer in contact with the connecting section is greater than an area of an orthographic projection of the contact surface of the source and drain layer in contact with the connecting section on the substrate.

11. A display device, comprising an array substrate, and the array substrate comprises:
a substrate;
an active layer arranged on the substrate, the active layer comprising an active section and a connecting section arranged on at least one side of the active section;
a source and drain layer, arranged on the connecting section and is in contact with the connecting section;
wherein an area of a contact surface of the source and drain layer in contact with the connecting section is greater than an area of an orthographic projection of the contact surface of the source and drain layer in contact with the connecting section on the substrate.

12. The display device according to claim 11, wherein a contact surface of the connecting section in contact with the source and drain layer comprises at least one first convex portion, and the source and drain layer comprises a first concave portion matching with the first convex portion.

13. The display device according to claim 12, wherein a supporting layer is provided between the active layer and the substrate, and the supporting layer comprises a supporting convex matching the first convex portion at a position corresponding to the first convex portion.

14. The display device according to claim 13, wherein a material of the supporting layer is of silicon oxide or silicon nitride.

15. The display device according to claim 12, wherein the contact surface of the active layer in contact with the source and drain layer comprises at least one second concave portion, and the source and drain layer comprises a second convex portion matching with the second concave portion.

16. The display device according to claim 11, wherein an insulating layer is provided on the source and drain layer, and the insulating layer covers the active layer and the source and drain layer, and a gate groove is formed in the insulating layer, and a gate layer is formed in the gate groove, and a surface of the insulating layer away from the source and drain layer and a surface of the gate layer away from the source and drain layer are coplanar.

17. The display device according to claim 11, wherein the connecting section comprises a first connecting section and a second connecting section respectively connected to the active section, and the source and drain layer comprises a source arranged on the first connecting section and a drain arranged on the second connecting section, and a contact area of the source with the first connecting section is greater than an area of an orthographic projection of a contact surface of the source in contact with the first connecting section on the substrate, or a contact area of the drain with the second connecting section is greater than an area of an orthographic projection of a contact surface of the drain in contact with the second connecting section on the substrate.

18. The display device according to claim 11, wherein the source and drain layer comprises an oxide metal layer and a metal layer, and the metal layer is connected to the connecting section through the oxide metal layer, and an area of a contact surface of the oxide metal layer in contact with the connecting section is less than an area of a contact surface of the oxide metal layer in contact with the source and drain layer.

19. The display device according to claim 18, wherein a thickness of the metal oxide layer is less than 5 nm, and a material of the metal oxide layer is titanium oxide, cobalt oxide or nickel oxide.

20. The display device according to claim 19, wherein the material of the metal oxide layer is nickel oxide.
